(19) United States
(12) Patent Application Publication
(10) Pub. No.: US 2013/0276868 A1
(43) Pub. Date: Oct. 24, 2013

(54) Solar Collector

(71) Applicant: Herbert Huemer, Vorchdorf (AT)

(72) Inventor: Herbert Huemer, Vorchdorf (AT)

(73) Assignee: Sun Master Energiesysteme GmbH, Eberstalzel (AT)

(21) Appl. No.: 13/513,847

(22) PCT Filed: Nov. 11, 2011
(86) PCT No.: PCT/AT2011/050029

§ 371 Date: Jul. 9, 2013

(30) Foreign Application Priority Data
Nov. 11, 2010 (AT) A 1855/2010

(51) Int. Cl. H01L 31/058; F24J 2/30

(52) U.S. Cl. CPC H01L 31/058; F24J 2/30
USPC 136/248; 126/646; 126/643; 126/714

(57) ABSTRACT

The invention relates to a solar collector (1) comprising a collector housing (2), an absorber (3) arranged therein and having a heating medium fluid (13) flowing through it, to absorb solar radiation (28), a return line (6) leading to the absorber (3) and a flow line (7) leading away from the absorber (3). Thereby a pump (14) is arranged on or at least partially inside the collector housing (2) for circulating a heating medium fluid (13) through the absorber (3).

The invention relates to a solar collector according to the preamble of Patent Claim 1 as well as a method for operating a solar collector according to the preamble of Claim 19.

Solar collectors are being used to an ever-increasing extent for the purposes of heating service water or for room heating. This is based on growing environmental awareness as well as scientific considerations.

It is standard today for pumps for circulating a heating medium fluid through solar collectors to be part of a so-called solar station, which is usually accommodated in a building to protect it from the weather, usually in a boiler room, where the solar collector system is also linked to other thermal installation parts and where the control system is also located. The operational reliability of a solar collector depends to a great extent on the solar collectors being tied into a hot water processing system and/or heating system. Installation expense and space required in addition to the actual mounting of the collector can be mentioned as disadvantages in installing such solar stations.

The object of the present invention is to provide a solar collector, which can be installed and also started up with little effort.

The object of the invention is achieved by a solar collector having the characterizing features of Claim 1. The arrangement of the circulating pump for the heating medium fluid in and/or on the solar collector makes it possible to omit a separate solar station within a building and thus reduces the complexity for installation and startup of a solar system thusly equipped. Due to the integration of the pump into or onto the solar collector, the degree of prefabrication is greater and therefore problems in circulation of the heating medium fluid due to possible errors in installation of the solar station can be eliminated from the beginning. Weather protection for the pump is thus provided by the sealing of the solar collector on its installation in the interior.

Due to an embodiment of the solar collector according to Claim 2 with a recooling function, the components of the solar collector reach much lower temperatures in the event of stagnation, i.e., in the absence of withdrawal of heat by the heat consumer, which is why the components of the solar collector can be produced using materials that meet lower thermal stability requirements and therefore may also be much less expensive than traditional high-temperature-resistant materials.

Simple regulation of the valve according to Claim 3 based on the return temperature of the heating medium fluid circulated by the heat consumer to the solar collector constitutes a simple and reliable approach because when the temperature falls below a temperature limit, there is evidently a heat demand on the heat consumer and/or heat storage capacity is free or when the temperature limit is exceeded there is no heat demand, and the heating medium fluid heated by the absorber is pumped back to the heat exchanger.

In the simplest case, the regulator and the valve may be formed by a thermostatically regulated 3/2-way valve on which one switch position connects the return line to the absorber and a second switch position connects the absorber to the heat exchanger, while the thermostat induces the circulation between the two switch positions. It is important here that the thermostat detects the temperature of the heating medium fluid in the return line. As soon as the heat consumer, for example, a hot water tank or a buffer storage has reached its maximum temperature, the temperature in the return line is high accordingly and switches the valve from supplying heat to removal of heat via the heat exchanger.

The power supply to the pump according to Claim 4 is achieved by a photovoltaic module mounted on the solar collector and causes the pump to be operated only when there is adequate solar radiation and it delivers the heat to the heat consumer for hot water processing or for the purpose of room heating. In the absence of demand for heat, the pump may also convey the heating medium fluid to a heat exchanger, which is optionally also present. In the absence or paucity of solar radiation, the inadequate power supply causes the pump to shut down, which thus lengthens its lifetime because it is in operation only when heat is being delivered either to the heat consumer or to the heat exchanger. The arrangement of the circulating pump in or on the solar collector and its power supply through a photovoltaic module mounted on the solar collector causes the solar collector to regulate itself to a certain extent in all operating states and therefore to have a high operational reliability because there is an autonomous recooling function in the stagnation case and therefore overheating problems are prevented. In addition, it is very simple to start operation of a such a solar collector because one need only connect the flow line and the return line to the heat consumer and the installation of power supply lines or control lines can be omitted entirely. Such a solar collector can be used universally with a high level of operational reliability and also allows simple startup of a solar collector system.

A convective flow develops due to the arrangement of the heat exchanger according to Claim 5 is advantageous because a convective flow is formed due to its hot surface and the usual inclination of a solar collector to the horizon, conveying the dissipated heat to the rear side of the solar collector. In addition, the area available on the front side for receiving solar radiation and generating electric power is not thereby reduced.

The design of the solar collector according to Claim 6 prevents unwanted dissipation of heat from the solar collector, with heat supplied to the heat consumers during normal operation, and prevents heat exchange between the absorber and the heat exchanger. The thermal insulation may consist of a mineral material, preferably mineral wool, as is also the case with traditional solar collectors, but because of the lower stagnation temperature, it is also possible to switch to organic insulation materials or polymer foams with a thermal stability of approx. 100° C.

An advantageous relationship between the structural complexity and the efficacy of the heat exchanger is achieved by a design according to Claim 7. Since the heat exchanger can deliver heat through convection as well as thermal radiation, it is possible to design the heat exchanger to be smaller than the absorber area and nevertheless adequate recooling of the heating medium fluid is achieved. The heat exchanger may also be formed by a portion of the rear wall of the collector housing to which a line carrying the heating medium fluid is attached, as in the case of the absorber, so there is a good heat transfer. In addition, it is possible that with a solar collector arrangement comprising a solar collector according to the invention, the additional solar collectors may be embodied as traditional collectors because circulation of the heating medium fluid can be accomplished by the one pump of the solar collector according to the invention. In the stagnation case the excess heat of the entire solar collector arrangement can be discharged via the heat exchanger of the solar collector according to the invention.

In an embodiment according to Claim 8, the quantity of heat that can be removed is maximized and the temperature may be kept even lower in the stagnation case.

The design of the solar collector according to Claim 9 is advantageous because it represents a balanced compromise between adequate electric current generation for reliable power supply to the pump and the least possible loss of absorber area.

The electric current connection between the photovoltaic module and the pump may be accomplished advantageously via a pulse control according to Claim 10, which activates the pump only in pulses and can thereby minimize power consumption. Due to the inertia of the heating medium fluid, it continues to flow into the lines for a short period of time even after the pump has been shut down. It is therefore possible to design the active area of the photovoltaic module to be smaller and to store the electric current generated in the pulse pauses in an energy storage mechanism, for example, in the form of a battery or a capacitor until the next pump pulse.

The implementation of the control unit according to Claim 11 makes it possible to transmit state data on the solar collector, in particular the flow temperature or its energy yield to a user of a solar collector according to the invention or to other persons using a public cell phone network, for example. Storage of such data for a later analysis may also be implemented through suitable storage devices.

Based on the low temperature of the components of the solar collector, which is also lower in the stagnation case, this may advantageously be embodied according to Claim 12, so that inexpensive materials may be used in manufacturing.

The embodiment of the solar collector according to Claim 13 permits an implementation of the independent autonomous regulation of the solar collector already described so that it has a simple design also with respect to the change between normal operation and the stagnation case.

Since the temperature of the heating medium fluid in the branch of the return line is generally lower than in the branch of the flow line, the design of the collector according to Claim 14 is advantageous and the temperature burden for the pump is therefore much lower.

Another measure for simpler installation and startup of a solar collector according to the invention consists of the embodiment according to Claim 15, so that separate installation of an equalizing vessel in the boiler room or other rooms outside of the solar collector may be omitted. The equalizing vessel is preferably also arranged inside the collector housing. The equalizing vessel serves to absorb a change in volume associated with the change in temperature of the heating medium fluid.

Further facilitation of the startup of a solar collector according to the invention is achieved according to Claim 16 because the collector can thereby be made ready to operate without using filling pumps. The filling connection may in particular also be arranged on the equalizing vessel described previously.

An embodiment according to Claim 17 is advantageous with regard to the design because the safety valve on the filling connection may at the same time also be used for filling the solar collector and/or the equalizing vessel. In addition, a line which opens into a collecting vessel so that any escaping heating medium fluid cannot enter the environment unhindered and/or can enter a roof drainage system may also be connected to the safety valve.

A solar collector according to the invention may advantageously also be connected to additional solar collectors, which may be traditional solar collectors, in a solar collector arrangement according to Claim 18 with additional solar collectors. In an embodiment with heat exchangers, the maximum number of traditional solar collectors without heat exchangers depends on the maximum possible dissipation of heat from the heat exchanger on the solar collector according to the invention and an upper maximum temperature must not be exceeded.

The invention also relates to a method for operating a solar collector according to Claim 19, according to which a pump for circulating the heating medium fluid is arranged on or at least partially inside the collector housing. Therefore it is possible to omit a separate solar station inside the building.

In addition, according to Claim 20 the heating medium fluid can be sent to the absorber through a heat exchanger in a recooling circuit in a valve-controlled process when a temperature limit is exceeded in the return line, and the pump can be supplied with electricity through a photovoltaic module arranged on the solar collector. This also triggers the autonomous and energy-autarkic mode of operation of such a solar collector in which damage due to overheating is prevented by the automatic recooling.

The solar collector according to the invention may be operated in particular as a so-called low-flow collector in which a relatively low throughput of the heating medium fluid is set, for example, up to 20 liters per square meter per hour, so that a relatively high flow temperature is available in a short period of time.

For a better understanding of the invention, it will now be explained in greater detail on the basis of the following figures.

They show each in a highly schematic simplified diagram:

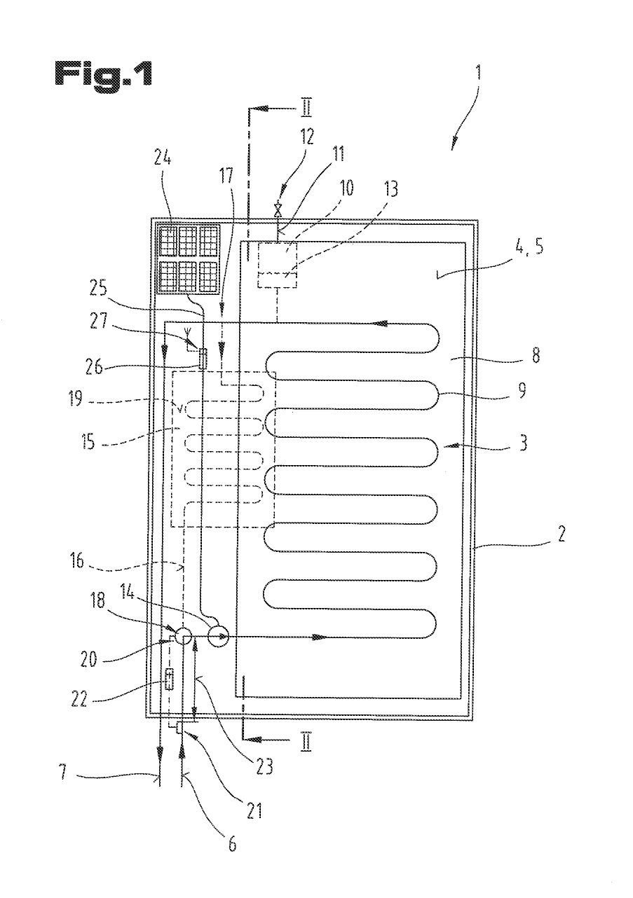

FIG. 1 a view of a solar collector according to the invention;

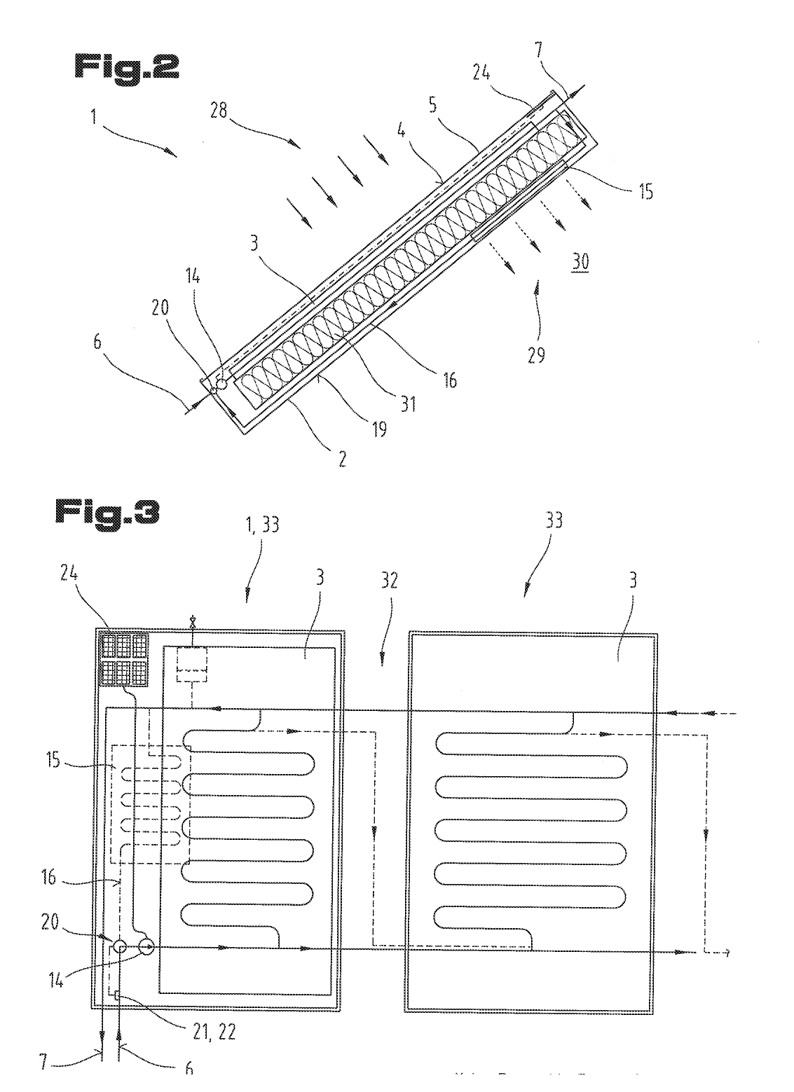

FIG. 2 a section through a solar collector according to the invention in the installed position according to line II-II;

FIG. 3 a solar collector arrangement comprising a solar collector according to the invention and a traditional solar collector in a parallel circuit or series connection.

As an introduction, it should be pointed out that the same parts in the different embodiments described below are labeled with the same reference numerals and/or the same component designations, wherein the disclosures contained in the entire description may also be transferred to the same parts. The position information, such as above, below, at the side, etc. used in the description refers to the figures, which are described in the text and are to be transferred accordingly to the new position when there is any change in position. Furthermore, individual features or combinations of features of the different exemplary embodiments shown and described here may constitute independent approaches according to the invention on their own.

All statements regarding value ranges in the present description are to be understood in such a way that they also include any and all partial ranges arising from them. For example, the statement of 1 to 10 is to be understood as including all partial ranges starting from the lower limit 1 and the upper limit 10, i.e., all partial ranges begin with a lower limit of one or more and end at an upper limit of 10 or less, e.g., 1 to 1.7 or 3.2 to 8.1 or 5.5 to 10.

FIG. 1 shows a view of a solar collector 1 which is suitable for converting solar radiation into thermal energy and is connected to a head consumer (not shown). The solar collector 1 comprises a collector housing 2 in which an absorber 3 is arranged which is exposed to the solar radiation. The collector housing 2 may be embodied in the form of a frame, which thus forms a frame collector or may also be embodied as a tray, for example, thus forming a so-called tray collector. The front side 4 of the solar collector 1 facing the solar radiation is preferably provided with a cover panel 5, which reduces the heat losses of the solar collector 1.

During operating, a heating medium fluid which is heated in the process flows through the absorber 3, so that the absorber 3 may be embodied as a surface or plate absorber or as a tubular absorber. A return line 6 leads from the heat consumer, for example, in the form of a hot water processing plant or a heating system, to the absorber 3, and a flow line 7 leads away from the absorber 3 to the heat consumer. In FIG. 1 the absorber 1 is embodied as a flat collector in which the solar radiation is absorbed by an absorber plate 8, formed by an aluminum foil or copper foil, for example. Heating medium fluid flows through a meandering or harp-type absorber line 9, shown in FIG. 1, which is welded to the absorber plate 8, thus achieving optimal heat transfer from the absorber plate 8 to the absorber line 9. The flow of heating medium fluid through the solar collector 1 is indicated by black arrowheads.

The temperature changes in the heating medium fluid that occur during operation cause a change in volume which is compensated by means of an optional equalizing vessel 10. This equalizing vessel 10 may advantageously be provided as a component of the solar collector 1 and in particular may be connected at the highest point of the absorber 3 and/or the return line 6 or the flow line 7 in the installed position of the solar collector 1. In addition, a filling connection 11 may be provided for filling the collector circuit, thereby allowing the heating medium fluid circuit to be filled easily. The filling connection 11 may also advantageously be provided with a safety valve 12 which protects the collector circuit from harmful excess pressures. As an alternative to the diagram in FIG. 1, the filling connection 11 may also be arranged separately from the equalizing vessel 10, but is preferably also connected to the highest point of the collector circuit.

The heating medium fluid 13 indicated in the equalizing vessel 10 fills the return line 6, the absorber line 9 and the flow line 7, i.e., the complete collector circuit.

The solar collector 1 also comprises a pump 14 with which the heating medium fluid 13 is conveyed through the collector circuit. In the exemplary embodiment shown here, the pump 14 is arranged in the branch of the return line 6 in which the heating medium fluid 13 to be heated is sent to the absorber 3. Since the temperature of the heating medium fluid 13 upstream from the absorber 3 is generally lower than that downstream from the absorber 3, the thermal burden on the pump 14 is therefore also lower. The pump 14 is preferably embodied as a rotary pump, and embodiments having a low power demand are preferred for use.

The pump is preferably arranged in such a way that it is readily accessible by being mounted outside of the collector housing 2 or is accessible through an opening in the latter to facilitate any maintenance that might be necessary. In addition, an arrangement in the equalizing vessel 10 is also possible.

The solar collector 1 may also advantageously comprise a heat exchanger 15 with which excess heat which can no longer be used by the heat consumer can be dissipated to the outside environment. This condition of lack of heat removal is also referred to as the stagnation state, and in traditional solar collectors, the circulation of the heating medium fluid 13 is often stopped in this state to avoid overheating the heat consumer and the installation associated with it. With traditional collector systems, the temperatures of the collector components may assume very high levels in this standstill of the heating medium fluid, but in a solar collector 1 with this design, the heating medium fluid 13 is passed by the absorber 3 through the heat exchanger 15, forming a recooling circuit 16 inside the solar collector 1, lowering the temperature of the heating medium fluid 13.

The heat exchanger 15 is connected to the return line 6 and/or to the flow line 7 in parallel with the absorber 3 and the pump 14 is inside the recooling circuit 16. The heat exchanger 15 is connected to the flow line 7 at a first line connection 17 and is connected to the return line 6 of the solar collector 1 at a second line connection 18, and the heating medium fluid 13 flows from the first line connection 17 at the flow line 7 in the direction of the second line connection 18 to the return line 6 for recooling the heating medium, such that the heat exchanger 15 releases heat to the outside environment and thereby lowers the temperature of the heating medium fluid 13.

The heat exchanger 15 may have a design similar to that of an absorber 3, for example, with a heat exchanger surface bordering on the outer environment, such that a line carrying the heating medium fluid 13 is attached to the heat exchanger surface with good thermal contact.

Alternatively, the absorber 3 and/or the heat exchanger 15 may also be embodied as plate heat exchangers in which the heating medium fluid is carried between two plates arranged in parallel with a small distance between them and not in a line of a small cross section.

The heat exchanger 15 is arranged on the rear side 19 of the solar collector 1 in the exemplary embodiment shown here and is shown with broken lines. The effective area of the heat exchanger 15 may be smaller than the absorber area, as shown in schematically in FIG. 1 for example, but it is also possible to maximize the usable area for the dissipation of heat in that the heat exchanger extends essentially over the entire rear side 19 or corresponds to at least 100% of the absorber area.

Whether the heating medium fluid 13 is carried from the absorber 3 over the flow line 7 to the heat consumer or from the absorber 3 in the recooling circuit 16 through the heat exchanger 15 is preferably controlled by means of a valve 20 that is regulated as a function of temperature. The temperature of the heating medium fluid 13 and the return line 6 is detected by means of a temperature sensor 21 or a temperature probe, and if this is beneath a certain temperature limit, the inlet line of the absorber 3 is connected to the return line 6 and therefore heating medium fluid 13 conveyed by the heat consumer is heated in the absorber 3 and returned back to the heat consumer via the flow line 7 or if the temperature detected is above a temperature limit, the heat exchanger 15 is connected to the absorber 3, and in the recooling circuit 16, the radiant energy absorbed by the absorber 3 is released to the heat exchanger 15 and from there as waste heat to the outside environment.

In the exemplary embodiment shown here, the valve 20 is arranged in the position of the second line connection 18 and it is also possible alternatively to arrange the valve 20 in the position of the first line connection 17 or to provide a valve both on the first line connection 17 and on the second line connection 18 so that it is also possible to switch between carrying the heating medium fluid 13 over the flow line 7 to the heat consumer or via the heat exchanger 15 back to the inlet of the absorber 3.

To activate the heat exchanger 15, the valve 20 is placed in the recooling position, for which purpose a regulator 22 is provided. This regulator 22 may be an independent component, but the regulating function may also be incorporated into the valve 20 or into the temperature sensor 21. For example, the valve 20 may be embodied as a 3/2 thermostatic valve which measures the temperature of the heating medium fluid 13 in the return line 6 either directly or indirectly. Another possibility for the regulator 22 is for the temperature sensor 21 to be designed as a thermostat and for a control drive of the valve 20 to be activated and/or for the direction of drive of a control drive to be changed according to the temperature prevailing in the return line 6.

The valve 20 may also be referred to as a reversing valve because in the simplest case it has only two switch positions, but an embodiment as a mixing valve is also conceivable by means of which the heating medium fluid 13 supplied to the absorber 3 is mixed in a variable division from the return line 6, i.e., from the heat consumer and from the heat exchanger 15. In particular an embodiment of the regulator 20 using thermally sensitive bimetals is also possible.

As already mentioned, the pump 14 is installed inside the recooling circuit 16, i.e., as shown in FIG. 1, between the second line connection 18 and the absorber 3, but alternatively it may also be arranged between the absorber 3 and the first line connection 17.

In order for the temperature sensor 21 not to be influenced by the recooling circuit 16, but instead to actually measure the temperature in the return line 6, the temperature sensor 21 is arranged at a distance 23 from the recooling circuit 16, for example, as shown in FIG. 1, just outside of the collector housing 2, where it is in contact with the outside environment and cools off during the recooling operation, i.e., when the recooling circuit 16 is activated, so that the temperature falls below the temperature limit, the valve 20 is switched and then heating medium fluid 13 from the return line 6 is again supplied to the absorber 3. If the latter has a temperature above the temperature limit, the valve is switched immediately back to recooling operation. Therefore automatic monitoring of the temperature in the return line 6 is ensured because after each cooling of the temperature sensor 21, heating medium fluid 13 is again carried from the heat consumer via the return line 6, at least briefly.

The distance 23 means that the temperature sensor 21 is thermally separated from the recooling circuit 16. It is also possible that the temperature sensor 21 is also arranged in the boiler room, for example, but this increases the installation complexity again.

The energy for operation of the pump 14 may be supplied via an electric power supply line, for example, from a boiler room, but, as shown in FIG. 1 as an example, it may also be provided by a photovoltaic module 24 arranged on the solar collector 1. It can be integrated into the solar collector housing 2 and/or covered with the cover disk 5 or arranged outside of the same or it is also conceivable to have an arrangement outside of the collector housing 2. The integrated arrangement however makes it possible to mount a solar collector 1 according to the invention directly adjacent to neighboring collector units and thereby utilize the available installation areas in the best possible way.

The photovoltaic module 24 can also be referred to as a solar module, which utilizes the photoelectric effect to convert the energy of solar radiation directly into electricity which can be used to supply the pump 14. In addition, the photoelectric module can also be used to supply power to the valve 20 having an optional valve drive, to supply the regulator 22, a control unit or the temperature sensor 21. All the conventional designs of solar modules are possible, wherein they may be produced, for example, using mono- or polycrystalline solar cells or also other types of solar cells and reference is made here to the known state of the art of photovoltaic modules 24.

The optically active surface of the photovoltaic module 24 is selected so that in the case of solar radiation which is suitable for rational thermal utilization, an adequate power supply voltage is also made available. With an integrated arrangement of the photovoltaic module 24, the optically active surface reduces the usable absorber area of the absorber 3, so it is advantageous if the optically active surface area is kept as small as possible and therefore designs with a high efficiency are to be preferred. For the sake of simplicity, FIG. 1 shows only one power supply line 25 between the photovoltaic module 24 and the pump 14, but it is also possible for additional power supply lines 25 to lead to other current consumers such as valve 20, temperature sensor 21 and regulator 22 which either lead directly away from the photovoltaic module 24 or branch off from the one power supply line 25. In another embodiment of the solar collector 1, a control unit 26 with which the operation of the pump 14 can be influenced may be provided, for example, in the course of the power supply line 25, in that the control unit 26 is designed as a pulse control, which activates the pump 14 only in pulses.

In addition, the control unit 26 may comprise a transmission unit 27, with which state data of the solar collector 1 can be transmitted to a user interface or a data memory. For example, the pump running time, the flow temperature, the return temperature, the thermal energy harvested, etc. can be transmitted to the user for his/her information or recorded in a data memory for subsequent analysis. Transmission to the user may take place in particular by way of a wireless network or a cell phone network, so that the user can be informed about the operating state of the solar collector 1 without having to remain in the vicinity of the boiler room or the solar collector 1.

The temperature of the heating medium fluid 13 can be kept at a relatively low level, for example, less than 95° C., in particular less than 85° C. by removing excess heat via the recooling circuit 16, so it is possible in the case of the solar collector 1 to design parts thereof such as the collector housing 2, the absorber 3, the heat exchanger 15 as well as the heating medium lines to be made predominantly of polymer materials. Therefore, in the case of a solar collector 1 furnished with a heat exchanger 15, lower manufacturing costs and/or weight savings can additionally be achieved without thereby shortening their lifetime.

FIG. 2 shows a section through a solar collector 1 having an integrated pump 14 according to line II-II in FIG. 1 as already described with reference to FIG. 1 and the same reference numerals have been entered in the figures for the same components or those having the same effect.

FIG. 2 shows an embodiment in which the solar radiation 30 incident upon the front side 4 of the solar collector 1 is released as waste heat 31 to the external environment 32 in the stagnation state, having been released by a heat exchanger 15 on the rear side 19 of the solar collector 1. The solar collector 1 is shown in an inclined installation position at an angle which is customary in the central latitude regions, which corresponds to the conventional roof mount or upright installation.

The absorber 3 is provided with a cover disk 5 on the front side 4 of the solar collector 1 to reduce waste heat losses, and thermal insulation 33 is also provided between the absorber 3 and the rear side 19 of the solar collector 1. With traditional solar collectors, this good thermal insulation of the absorber 3 is responsible for the fact that very high temperatures occur in the stagnation case, and these temperatures can have a negative effect on the components of the solar collector and the heating medium fluid 13 and can greatly shorten their lifetime.

FIG. 2 also shows the recooling circuit 16 and the direction of flow of the heating medium fluid 13 indicated with arrowheads.

FIG. 3 shows a solar collector arrangement 32 comprising at least two solar collectors 33 connected in series connection or parallel connection such that at least one solar collector 33 is designed as the solar collector 1 according to the invention. To avoid repetition with respect to the design and operation of the solar collector 1, reference is made to the description of the preceding FIGS. 1 and 2.

In FIG. 3 the solar collector 33 on the left is embodied as the solar collector 1 according to the invention which comprises an optional heat exchanger 15 in addition to the absorber 3 and the pump 14. The circulation of the heating medium fluid 13 through the entire solar collector arrangement 32 can be accomplished here by the pump 14 of the solar collector 1 according to the invention, so there is no need for additional pumps or a solar station in the boiler room. The pump 14 is preferably again supplied with power from a photovoltaic module 24. Switching between normal operation and recooling operation is performed by means of a valve 20, which is adjusted by means of a regulator 22 as a function of the measured temperature, based on the temperature measured in the return line 6 by means of the temperature sensor 21.

Another solar collector 33 which in the exemplary embodiment shown here is designed as a traditional solar collector without a pump 14, heat exchanger 15 or photovoltaic module 24 is connected to the solar collector 1 according to the invention. The additional solar collector 33 may be connected in parallel to the first solar collector 1, as shown with solid lines, or alternatively may also be connected in series with the first solar collector 1, as indicated with dotted lines. In the two variants of connections, the optional recooling circuit 16 also extends to the additional solar collector(s) 33 in the stagnation case, so that the latter are also exposed to lower temperature burdens. The heat exchanger surface of the heat exchanger 15 may also be designed to be larger in the solar collector 1 according to the invention so that only one solar collector 1 according to the invention is necessary in the case of a solar collector arrangement 32 comprising a larger number of solar collectors 33. The advantageous effects of the solar collector 1 according to the invention include simple installation as well as the automatic temperature limitation in the stagnation case, which occurs in the additional embodiments, as well as the monitoring of the heat demand by temperature measurement in the return line 6; these advantageous effects also influence the overall solar collector arrangement 32.

The exemplary embodiments show possible variants of embodiments of the solar collector 1, but it should be pointed out here that the invention is not limited to the specific variants of embodiments shown here but instead also includes various combinations of the individual variants among one another and these possible variations are within the abilities of those skilled in the art in this technical field based on the teaching for technical action provided by the present invention. Thus all conceivable variants which are possible by combining individual details of the variants depicted and described here are accessible to separate protection, possibly by filing divisional applications.

For the sake of order, it should also be pointed out in conclusion that in some cases the design of the solar collector and/or its components have been shown enlarged and/or reduced and/or not drawn to scale merely to facilitate a better understanding of the design of the solar collector.

The object on which the independent approaches according to the invention have been based can be derived from the description.

In particular the individual embodiments illustrated in FIGS. 1; 2; and 3 form the subject matter of independent approaches according to the invention. The problems and solutions in this regard according to the invention can be derived from the detailed descriptions of these figures.

1. A solar collector comprising:
a collector housing;
an absorber arranged therein and having a heating medium fluid flowing through it configured to absorb solar radiation;
a return line leading to the absorber; and
a flow line leading away from the absorber, wherein
a pump is configured to be arranged on or at least partially inside the collector housing for circulating a heating medium fluid through the absorber.

2. The solar collector of claim 1, further comprising
a heat exchanger which is configured to be connected to the return line and to the flow line by means of at least one valve thereby forming a recooling circuit with the absorber in a recooling position of the valve and is further configured to connect to the external environment of the solar collector, wherein the heating medium fluid can be circulated through the recooling circuit by the pump.

3. The solar collector of claim 2 wherein further comprising:
a temperature-dependent regulator for adjusting the valve and is configured to be arranged in or on the solar collector.

4. The solar collector of claim 1, wherein
the pump is configured to connect to a photovoltaic module arranged on the solar collector to supply the electricity.

5. The solar collector of claim 2, Wherein
the heat exchanger is arranged on the rear side of the solar collector.

6. The solar collector of claim 2, wherein
the heat exchanger is configured to be thermally separated from the absorber by thermal insulation.

7. The solar collector of claim 2, wherein
the heat exchanger has a heat exchanger surface which amounts to between 20% and 95% of the absorber surface area.

8. The solar collector of claim 2, wherein
the heat exchanger has a heat exchanger surface which amounts to 100% of the absorber surface or is formed essentially by the entire rear side of the solar collector.

9. The solar collector of claim 4, wherein
the photovoltaic module has an optically active surface amounting to between 2% and 30% of the absorber surface area.

10. The solar collector of claim 4,
further comprising a control unit, in particular a pulse control unit on a power connection line between the photovoltaic module and the pump.

11. The solar collector of claim 10, wherein
the control unit is configured to connect to a transmitter unit for which is configured to transmit state data of the solar collector to a user interface or a data memory in particular for wireless transmission, wherein the state data comprises at least one property selected from a group consisting of: the pump running time, the flow temperature and the return temperature.

12. The solar collector of claim 1, wherein
at least one of the components including the flow line, return line, absorber, heat exchanger, collector housing, and thermal insulation is formed primarily from polymer material.

13. The solar collector of claim 3, wherein
the regulator is controlled by a temperature sensor, arranged on the return line and placed a distance away from the recooling circuit.

14. The solar collector of claim 2, wherein
the pump is arranged in the branch of the return line in the return circuit.

15. The solar collector of claim 1,
wherein the absorber is connected to an equalizing vessel arranged above the absorber in an installed position of the solar collector and preferably arranged within the collector housing.

16. The solar collector of claim 1,
wherein the absorber has a sealable filling connection at its highest point in an installed position of the solar collector.

17. The solar collector of claim 16, wherein
the filling connection is provided with a safety valve.

18. A solar collector arrangement, comprising two or more solar collectors connected in series connection or in parallel connection,
wherein
at least one solar collector comprising:
a collector housing;
an absorber arranged therein and having a heating medium fluid flowing through it configured to absorb solar radiation;
a return line leading to the absorber; and
a flow line leading away from the absorber, wherein a pump is configured to be arranged on or at least partially inside the collector housing for circulating a heating medium fluid through the absorber.

19. A method for operating a solar collector, wherein a heating medium fluid is carried to a flow line from a return line through an absorber arranged in a collector housing and facing the solar radiation, wherein
the heating medium fluid is circulated by a pump arranged on or at least partially inside the collector housing.

20. The method according to claim 19 wherein
the heating medium fluid is carried through a heat exchanger in a return circuit downstream from the absorber in a valve-controlled process when a temperature limit is exceeded in the return line and the pump is supplied with electricity by a photovoltaic module arranged on the solar collector.
